(19) United States
(12) Patent Application Publication
(10) Pub. No.: US 2025/0046702 A1
(43) Pub. Date: Feb. 6, 2025

(54) SEMICONDUCTOR STRUCTURE INCLUDING CRACK DETECTOR AND MANUFACTURING METHOD THEREOF

(71) Applicant: TAIWAN SEMICONDUCTOR MANUFACTURING COMPANY LTD., HSINCHU (TW)

(72) Inventors: WEI-YU CHOU, TAICHUNG CITY (TW); YANG-CHE CHEN, HSIN-CHU CITY (TW); TING-YUAN HUANG, YILAN COUNTY (TW); TSE-WEI LIAO, HSINCHU CITY (TW); CHENG-YU HSIEH, KAOHSIUNG CITY (TW); HSIANG-TAI LU, HSINCHU COUNTY (TW)

(21) Appl. No.: 18/365,252

(22) Filed: Aug. 4, 2023

(51) Int. Cl. H01L 23/522

(52) U.S. Cl. CPC H01L 23/5223; H01L 28/60

(57) ABSTRACT

A semiconductor structure includes an interconnect structure, a passivation structure, a first capacitor, and a contact feature. The interconnect structure is disposed over a semiconductor substrate. The passivation structure is disposed over the interconnect structure. The first capacitor is disposed within the passivation structure. The contact feature is disposed over the passivation structure, wherein the first capacitor is proximal to a corner of the contact feature. A method of manufacturing the semiconductor structure is also provided.

### BACKGROUND

Consumers continue to demand products having higher performance and lower cost. Such features require increased miniaturization of components and greater packaging density of integrated circuits (“ICs”). The increasing functionality and decreasing size and number of system components make ICs more and more susceptible to damage during manufacturing and in use. Integrated circuit packages are commonly used to encase the IC and its connections to electrical interconnections. The integrated circuit package both protects the circuit and provides electrical interconnections to external circuitry. Stresses induced by environmental factors and manufacturing factors result in cracks on an IC package and further affect electrical properties of the IC package.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, dimensions of the various features may be arbitrarily increased or reduced for clarity of discussion.

FIG. 1 is a schematic cross-sectional diagram of a semiconductor structure in accordance with some embodiments of the present disclosure.

FIG. 2 is a schematic cross-sectional diagram of a semiconductor structure in accordance with some embodiments of the present disclosure.

FIGS. 3 to 10 are schematic cross-sectional diagrams showing formation of a capacitor structure in a passivation structure at different stages of a manufacturing method in accordance with some embodiments of the present disclosure.

FIG. 11 is a schematic cross-sectional diagram of a semiconductor structure in accordance with some embodiments of the present disclosure.

FIGS. 12 to 20 are schematic cross-sectional diagrams at different stages of a manufacturing method in accordance with some embodiments of the present disclosure.

FIGS. 21 to 23 are schematic cross-sectional diagrams of semiconductor structures in accordance with different embodiments of the present disclosure.

FIGS. 24 to 26 are top-view perspectives showing contact features and capacitor structures in accordance with different embodiments of the present disclosure.

FIG. 27 is a flow diagram of a method of manufacturing a semiconductor structure in accordance with different embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context. In addition, the term “source/drain region” or “source/drain regions” may refer to a source or a drain, individually or collectively dependent upon the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from normal deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages, such as those for quantities of materials, durations of time, temperatures, operating conditions, ratios of amounts, and the likes thereof disclosed herein, should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

A semiconductor structure may undergo multiple thermal cycles during a manufacturing process, and a mismatch between thermal expansion coefficients (CTE) of two different materials is an unavoidable issue that can result in cracks in the semiconductor structure. In additions to the CTE mismatch, a bending stress between bumps and a substrate during a packaging process can also result in cracks in the semiconductor structure. Such cracks allow moisture to enter the semiconductor structure through the cracks, and electrical properties of electrical components in the semiconductor structure change after absorbing moisture. Product yield can be affected. An optical examination is applied to detect the cracks in a semiconductor structure to ensure a quality of the semiconductor structure prior to the packaging process. However, optical examination is inefficient and prone to misrecognition.

The present disclosure provides a semiconductor structure including a capacitor structure in a dielectric material layer, such as in a passivation layer or proximal to an upper surface of the semiconductor structure. The capacitor structure of the present disclosure is designed to be disposed at locations where cracks are likely to occur. If a crack is present, the crack causes reduction or change in a capacitance of the capacitor structure after absorbing moisture. Therefore, the semiconductor structure of the present disclosure can be easily examined through an electronic measurement in order to exclude damaged semiconductor structures prior to packaging. Manufacturing cost can be reduced and product yield can be improved. In addition, according to a location of the capacitor structure in the semiconductor structure, a position of the crack on a surface of the semiconductor structure and a depth of the crack extending into the semiconductor structure can be identified for purposes of evaluation and adjustment of manufacturing processes and improvement of the semiconductor structure.

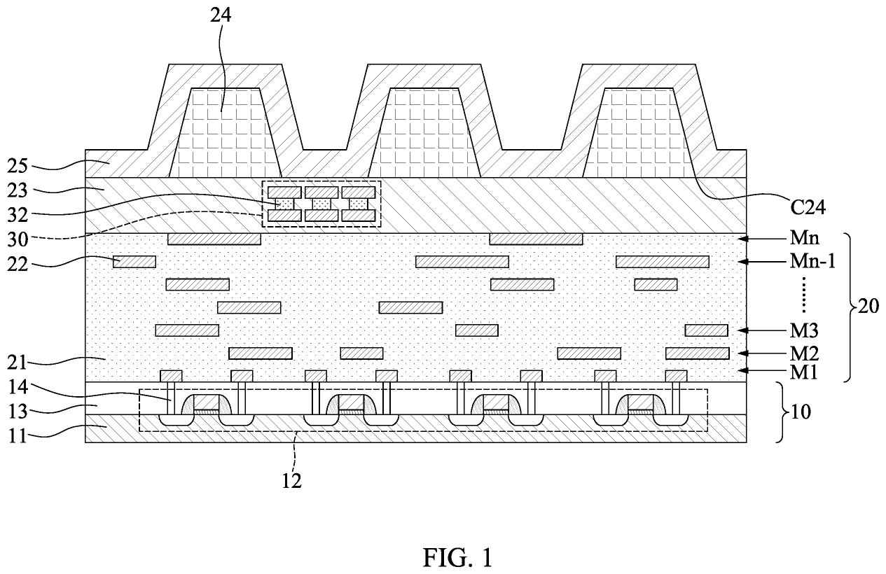

FIG. 1 is a schematic cross-sectional diagram of a semiconductor structure in accordance with some embodiments of the present disclosure. The semiconductor structure includes a substrate 10, an interconnect structure 20, a capacitor structure 30, a first passivation structure 23, a second passivation structure 25, and a plurality of contact features 24.

The substrate 10 may include one or more electrical components 12 formed on a semiconductive layer 11. The semiconductive layer 11 can include a bulk semiconductor material, such as silicon. Alternatively, the semiconductive layer 11 may include another elementary semiconductor, such as germanium; a compound semiconductor including silicon carbide, gallium arsenic, gallium phosphide, indium phosphide, indium arsenide, or indium antimonide; an alloy semiconductor including SiGe, GaAsP, AlInAs, AlGaAs, GaInAs, GaInP or GaInAsP; or combinations thereof. The semiconductive layer 11 may be of a first conductivity type, e.g., a P-type semiconductive substrate (acceptor type), or of a second conductivity type, e.g., an N-type semiconductive substrate (donor type). In some embodiments, the semiconductive layer 11 is a semiconductor-on-insulator (SOI). In some embodiments, the semiconductive layer 11 includes a doped epitaxial layer, a gradient semiconductor layer, or a semiconductor layer overlaying another semiconductor layer of a different type, such as a silicon layer on a silicon germanium layer.

The electrical components 12 can be active components or devices, and may include different types or generations of devices. The electrical components 12 can include a planar transistor, a multi-gate transistor, a gate-all-around field-effect transistor (GAAFET), a fin field-effect transistor (FinFET), a vertical transistor, a nanosheet transistor, a nanowire transistor, or a combination thereof. For a purpose of simplicity, planar transistors are depicted in FIG. 1 as an exemplary embodiment of electrical components, but such depiction is not intended to limit the present disclosure.

The substrate 10 may further include an insulating layer 13 formed over the semiconductive layer 11, and a plurality of contact vias 14 formed in the insulating layer 13 and electrically connected to the electrical components 12. In some embodiments, the contact vias 14 are connected to a source region, a drain region and a gate region of a transistor (which can be one of the electrical components 12). In some embodiments, the contact vias 14 are electrically isolated from one another by the insulating layer 13. The contact vias 14 provide electrical connection between the electrical components 12 and metal lines 22 in the interconnect structure 20.

The interconnect structure 20 is disposed over the substrate 10. The interconnect structure 20 may include multiple layers of the metal lines 22. For a purpose of illustration, the interconnect structure 20 can include a plurality of metal line layers M1 to Mn, wherein n is a positive integer greater than 1. The metal line layer Mn can represent a topmost metal line layer of the interconnect structure 20. In some embodiments, the top two metal line layers Mn and Mn−1 are collectively referred to as top metal layers. The interconnection structure 20 may further include multiple metal via layers (not shown in FIG. 1) arranged alternately between the metal line layers M1 to Mn for electrical connection between the metal line layers M1 to Mn. In some embodiments, each of the metal line layers M1 to Mn is formed of metal lines and an intermetal dielectric (IMD) layer surrounding the metal lines. In some embodiments, each of the metal via layers is formed of metal vias and an IMD layer surrounding the metal vias. The IMD layers surrounding the metal lines and the IMD layers surrounding the metal vias are collectively referred to as an IMD structure 21. In some embodiments, conductive features (including the metal lines and the metal vias) of the interconnect structure 20 include tungsten (W), aluminum (Al), copper (Cu), silver (Ag), gold (Au), titanium (Ti), tantalum (Ta), ruthenium (Ru), tungsten (W), titanium-nitride (TiN), tantalum-nitride (TaN), ruthenium nitride (RuN), tungsten nitride (WN), and alloys thereof.

The first passivation structure 23 is disposed over the interconnect structure 20, and can include one or more passivation layers (detailed description is provided below in discussion of a forming method thereof). The first passivation structure 23 may be formed of a dielectric material, such as undoped silicate glass (USG), silicon nitride, silicon oxide, silicon oxynitride, a non-porous material, polymer (such as polyimide), or other suitable dielectric material, and may be formed by any suitable method, such as chemical vapor deposition (CVD), physical vapor deposition (PVD), or the like. In some embodiments, a thickness of the first passivation structure 23 is in a range of 0.8 to 1.4 microns (μm). In some embodiments, the first passivation structure 23 includes a low-k dielectric material. In some embodiments, a dielectric constant of the first passivation structure 23 is substantially equal to or less than 3.9.

The plurality of contact features 24 are disposed over the first passivation structure 23. The contact features 24 can be formed of aluminum, aluminum copper, aluminum alloys, copper, copper alloys, or a combination thereof. Alternatively, the contact features 24 can be lead (Pb) solders, Pb-free solders, or a tin-silver solder on a copper pillar. In some embodiments, the contact features 24 include a conductive material different from those of the metal lines or the metal vias of the interconnect structure 20.

The second passivation structure 25 is disposed over the first passivation structure 23 and covers the contact features 24. The second passivation structure 25 can be similar to the first passivation structure 23, and repeated description is omitted herein.

The capacitor structure 30 is disposed within the first passivation structure 23 and proximal to a lower corner C24 of a contact feature 24. In some embodiments, the capacitor structure 30 is at an elevation lower than an elevation of the contact features 24. In some embodiments, the capacitor structure 30 is disposed between two adjacent contact features 24. The capacitor structure 30 electrically connects to one of the contact features 24, for example, through a conductive via (not shown), for a purpose of electrical measurement of a capacitance of the capacitor structure 30.

In some embodiments, the capacitor structure 30 is physically separated from the interconnect structure 20 by a portion of the first passivation structure 23 underlying the capacitor structure 30. In some embodiments, a vertical distance between a bottom surface of the capacitor structure 30 and a top surface of the interconnect structure 20 is in a range of 0.2 to 0.6 μm. In some embodiments, the capacitor structure 30 is physically separated from the second passivation structure 25 by a portion of the first passivation structure 23 covering the capacitor structure 30. In some embodiments, a vertical distance between a bottom surface of the contact feature 24 and a top surface of the capacitor structure 30 is in a range of 0.2 to 0.6 μm. In some embodiments, the capacitor structure 30 is entirely within the first passivation structure 23. In some embodiments, a thickness of the capacitor structure 30 is in a range of 0.2 to 0.4 μm. In some embodiments, the capacitor structure 30 is partially overlapped by an adjacent contact feature 24.

The capacitor structure 30 is for a purpose of moisture detection, and a capacitance of the capacitor structure 30 is an index of moisture. The capacitance of the capacitor structure 30 drops if the capacitor structure 30 absorbs moisture, which indicates a presence of a crack in the semiconductor structure. For ease of detection, an insulator 32 of the capacitor structure 30 is made of high-k dielectric material. In some embodiments, a dielectric constant of the insulator 32 is in a range of 8 to 30. In addition, a material of the insulator 32 can be selected from dielectric materials that readily absorb moisture, such as porous material. In some embodiments, an examination of stress zones of the semiconductor structure is provided, and the capacitor structure 30 is placed proximal to or at the stress zones, where a crack easily occurs.

For a purpose of illustration and simplicity of the figures, only one capacitor structure 30 in the first passivation structure 23 is depicted in FIG. 1. However, it is not intended to limit the present disclosure. In some embodiments, the semiconductor structure includes multiple capacitor structures 30 at different regions of the first passivation structure 23.

In addition, the semiconductor structure of the present disclosure can include multiple capacitor structures 30 at different elevations for a purpose of detection of a depth of a crack extending into the semiconductor structure.

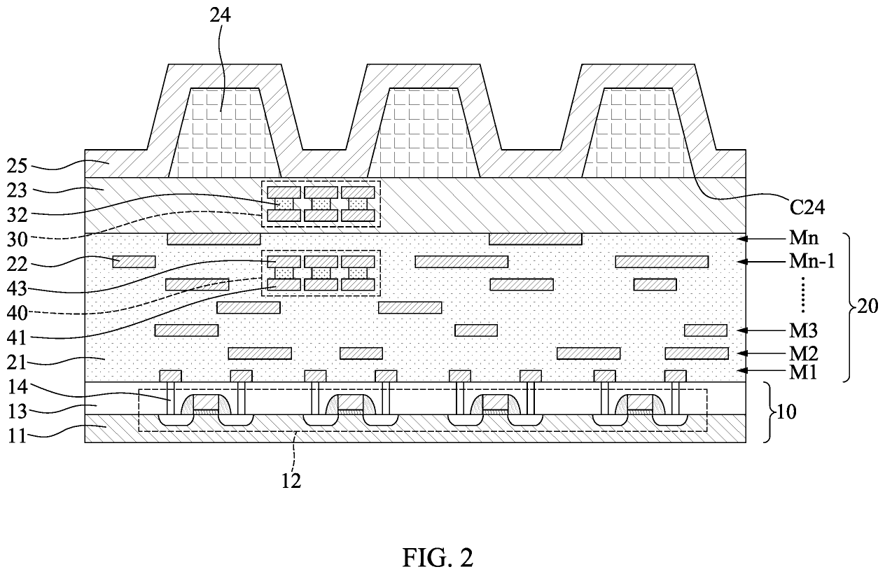

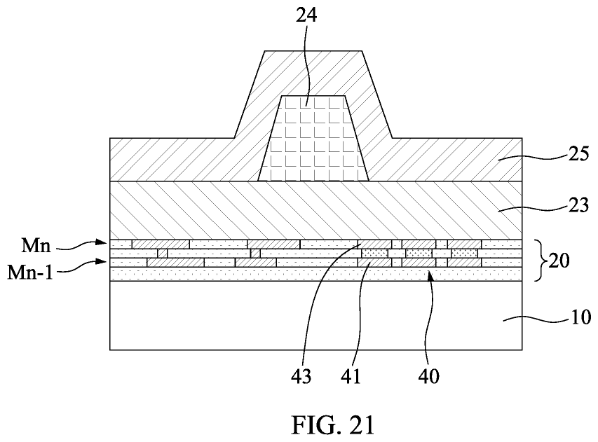

FIG. 2 is a schematic cross-sectional diagram of a semiconductor structure in accordance with some embodiments of the present disclosure. The semiconductor structure shown in FIG. 2 is similar to the semiconductor structure shown in FIG. 1 but further includes a capacitor structure 40 disposed in the interconnect structure 20. In some embodiments, the capacitor structure 40 is overlapped by the capacitor structure 30 for a purpose of detection of a vertical distance of a crack. In some embodiments, the capacitor structure 40 may be entirely overlapped by the capacitor structure 30. In other embodiments, the capacitor structure 40 may be partially overlapped by the capacitor structure 30. An elevation of the capacitor structure 40 can depend on a specification of an application. In some embodiments, an upper electrode 43 and a lower electrode 41 of the capacitor structure 40 are disposed in different metal line layers (details of which are provided below, in a description of a forming method of the capacitor structure 40). In some embodiments, the capacitor structure 40 is disposed in a metal line layer below the topmost metal line layer Mn as shown in FIG. 2. In alternative embodiments, the capacitor structure 40 can be disposed in the topmost metal line layer Mn (as shown in FIGS. 21 to 23). In some embodiments, the capacitor structure 40 is vertically separated from the capacitor structure 30 by a default distance.

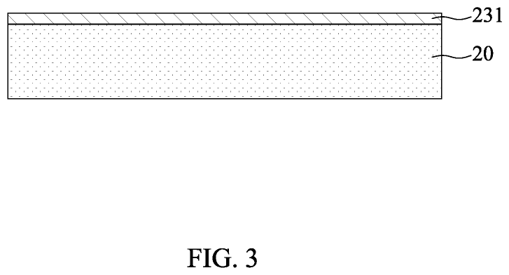

FIGS. 3 to 10 are schematic cross-sectional diagrams showing formation of the capacitor structure 30 in the first passivation structure 23 at different stages of a manufacturing method in accordance with some embodiments of the present disclosure.

Referring to FIG. 3, a first passivation layer 231 is formed over the interconnect structure 20. The first passivation layer 231 can be formed by CVD, PVD, or another suitable method. In some embodiments, a thickness of the first passivation layer 231 is in a range of 0.2 to 0.6 μm. A material of the first passivation layer 231 can be one of the selection of materials of the first passivation structure 23 described above, and repeated description is omitted herein. In some embodiments, the first passivation layer 231 includes a low-k dielectric material.

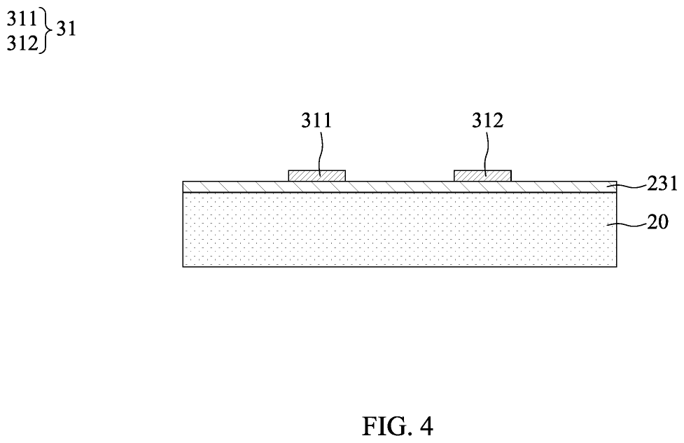

Referring to FIG. 4, lower electrodes 31 are formed over the first passivation layer 231. The lower electrodes 31 can include lower electrodes 311 and 312. In some embodiments, the lower electrodes 311 and 312 are electrically connected. In some embodiments, the lower electrodes 311 and 312 are physically connected from a top view (not shown). The lower electrodes 31 can include a suitable conductive material, such as tungsten (W), aluminum (Al), copper (Cu), silver (Ag), gold (Au), titanium (Ti), tantalum (Ta), ruthenium (Ru), tungsten (W), titanium-nitride (TiN), tantalum-nitride (TaN), ruthenium nitride (RuN), tungsten nitride (WN), alloys thereof, or a combination thereof. The lower electrodes 311 and 312 can be formed by a sequence of operations. In some embodiments, a plating operation or a deposition followed by a patterning operation is performed to form the lower electrodes 311 and 312 over the first passivation layer 231.

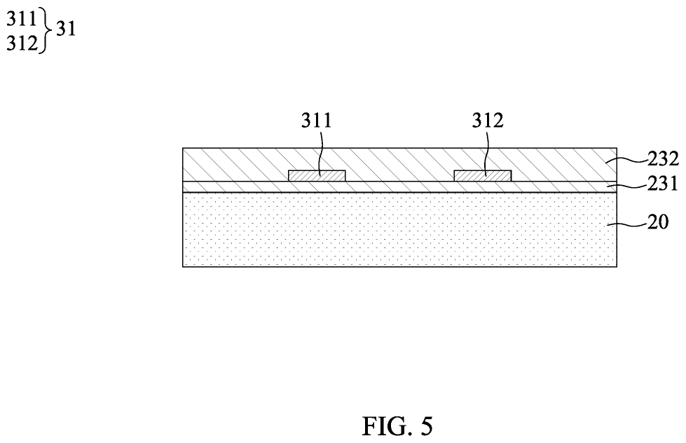

Referring to FIG. 5, a second passivation layer 232 is formed over the lower electrodes 31 and the first passivation layer 231. In some embodiments, the second passivation layer 232 covers an entirety of the lower electrodes 31. In some embodiments, the second passivation layer 232 covers an entirety of the first passivation layer 231. A material and formation of the second passivation layer 232 can be similar to those of the first passivation layer 231, and repeated description is omitted herein. In some embodiments, the second passivation layer 232 includes a low-k dielectric material. In some embodiments, a thickness of the second passivation layer 232 is substantially greater than a thickness of the lower electrodes 31. In some embodiments, a top surface of the second passivation layer 232 is substantially planar.

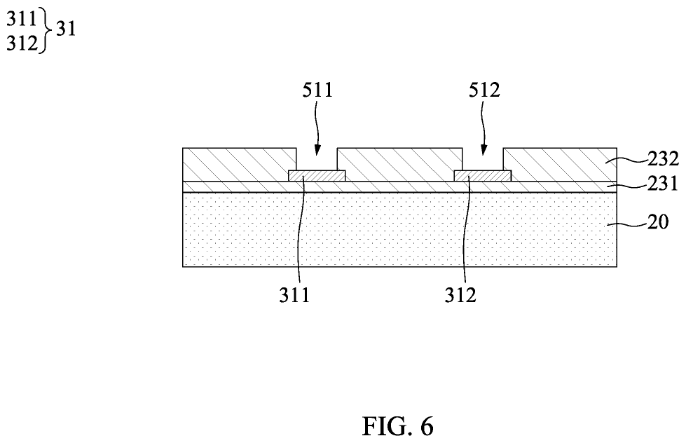

Referring to FIG. 6, openings 511 and 512 are formed in the second passivation layer 232 to expose portions of the lower electrode 311 and the lower electrode 312, respectively. In some embodiments, an etching operation is performed to form the openings 511 and 512. In some embodiments, a patterned mask layer is formed over the second passivation layer 232 prior to the etching operation. In some embodiments, the etching operation is performed on the second passivation layer 232 using the patterned mask layer as a mask.

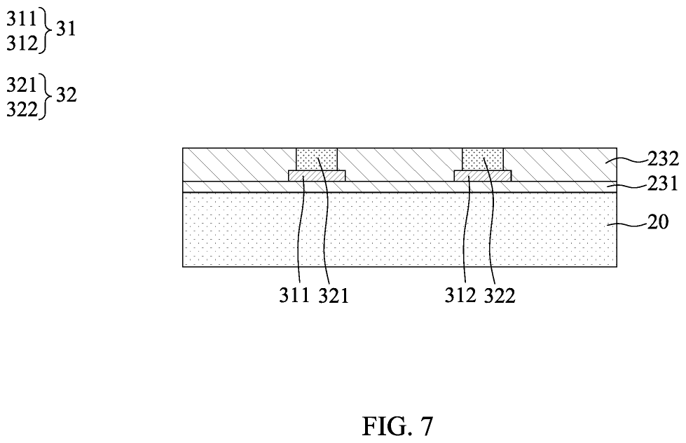

Referring to FIG. 7, insulators 32 (including insulators 321 and 322) are formed in the openings 511 and 512. In some embodiments, a high-k dielectric material is formed over the second passivation layer 232. In some embodiments, the high-k dielectric material fills the openings 511 and 512 shown in FIG. 6 and covers the top surface of the second passivation layer 232. In some embodiments, a dielectric constant of the insulators 32 is greater than a dielectric constant of the first passivation layer 231 or the second passivation layer 232. In some embodiments, an etching operation is performed to remove the high-k dielectric material above the second passivation layer 232, thereby forming the insulators 321 and 322 in the openings 511 and 512, respectively. In some embodiments, each of the insulators 32 is laterally surrounded by the second passivation layer 232. In some embodiments, the insulators 32 are in direct contact with the second passivation layer 232. In some embodiments, the dielectric constant of the high-k dielectric material is in a range of 8 to 30. In some embodiments, the insulator 321 is disposed within an area of a vertical projection of the lower electrode 311. In some embodiments, the insulator 322 is disposed within an area of a vertical projection of the lower electrode 312.

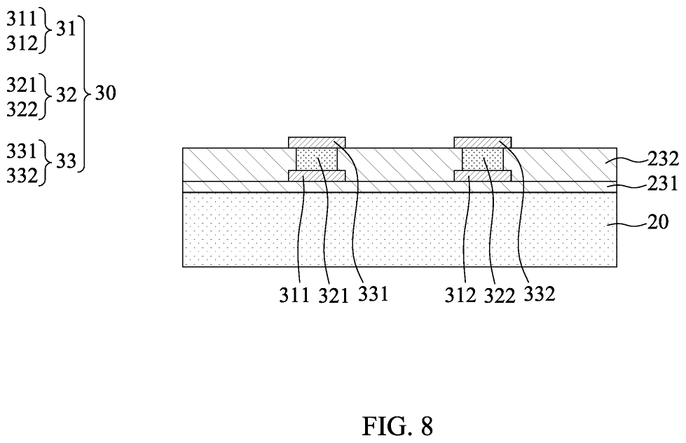

Referring to FIG. 8, upper electrodes 33 (including upper electrodes 331 and 332) are formed over the second passivation layer 232 and the insulators 32. Formation of the upper electrodes 33 can be similar to that of the lower electrodes 31, and repeated description is omitted herein. In some embodiments, the upper electrodes 33 include a conductive material same as that of the lower electrodes 32. In some embodiments, the upper electrode 331 overlaps an entirety of the insulator 321. In some embodiments, the upper electrode 332 overlaps an entirety of the insulator 322. In some embodiments, the insulator 321 is disposed within an area of a vertical projection of the upper electrode 331. In some embodiments, the insulator 322 is disposed within an area of a vertical projection of the upper electrode 332.

The lower electrodes 31, the insulators 32 and the upper electrodes 33 form the capacitor structure 30. In some embodiments, the capacitor structure 30 is a capacitor array including two electrically connected capacitors. In some embodiments, the capacitor structure 30 is a single capacitor having a ring configuration from a top view. In some embodiments, the capacitor structure 30 a single capacitor having a U shape from a top view. A configuration from a top view of the capacitor structure 30 is not limited herein. A thickness of the capacitor structure 30 is substantially equal to a total thickness of the lower electrode 311, the insulator 321 and the upper electrode 331 (or a total thickness of the lower electrode 312, the insulator 322 and the upper electrode 332). In some embodiments, the thickness of the capacitor structure 30 is in a range of 0.2 to 0.4 μm.

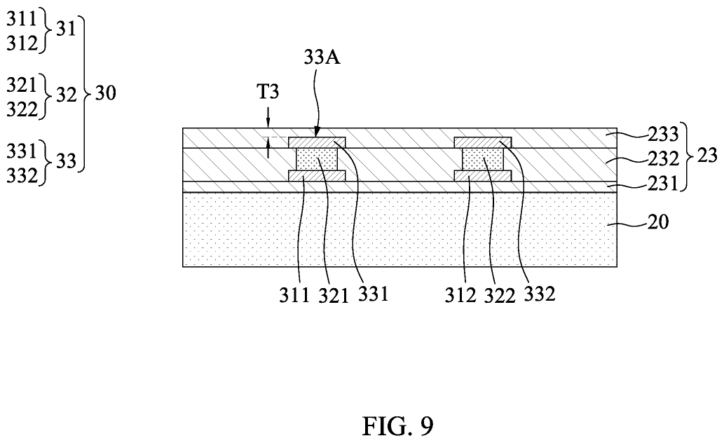

Referring to FIG. 9, a third passivation layer 233 is formed over the upper electrodes 33 and the second passivation layer 232. In some embodiments, the third passivation layer 233 covers an entirety of the upper electrodes 33. In some embodiments, the third passivation layer 233 covers an entirety of the second passivation layer 232. A material and formation of the third passivation layer 233 can be similar to those of the first passivation layer 231 or the second passivation layer 232, and repeated description is omitted herein. In some embodiments, a thickness T3 of a portion of the third passivation layer 233 over a top surface 33A of the upper electrodes 33 is in a range of 0.2 to 0.6 μm. In some embodiments, a top surface of the third passivation layer 233 is substantially planar. The first passivation layer 231, the second passivation layer 232 and the third passivation layer 233 are collectively referred to as a first passivation structure 23. In some embodiments, a total thickness of the first passivation layer 231, the second passivation layer 232 and the third passivation layer 233 is in a range of 0.8 to 1.4 μm.

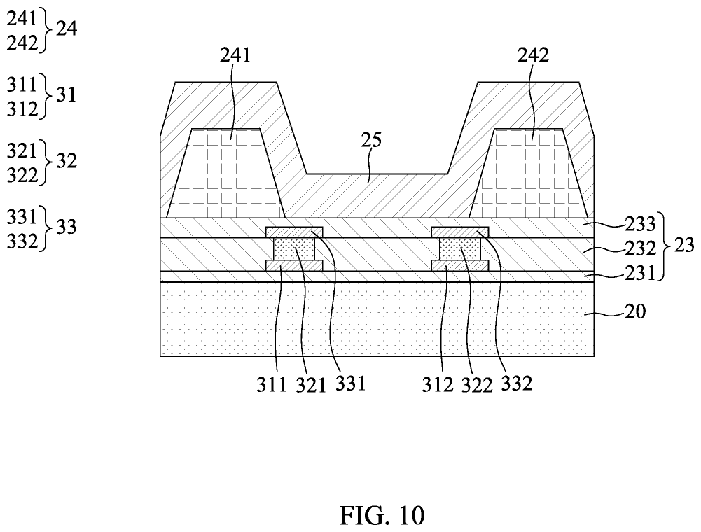

Referring to FIG. 10, a plurality of contact features 24 are formed over the third passivation layer 233, and a second passivation structure 25 is formed over the contact features 24 and the third passivation layer 233. The second passivation structure 25 can include one or more passivation layers, depending on different applications. In some embodiments, the second passivation structure 25 is conformal to a profile of the contact features 24. In some embodiments, a top surface of the second passivation structure 25 is substantially planar.

The capacitor structure 30 shown in FIG. 10 includes vertically stacked lower electrodes 31, insulators 32 and upper electrodes 33. However, the present disclosure is not limited thereto.

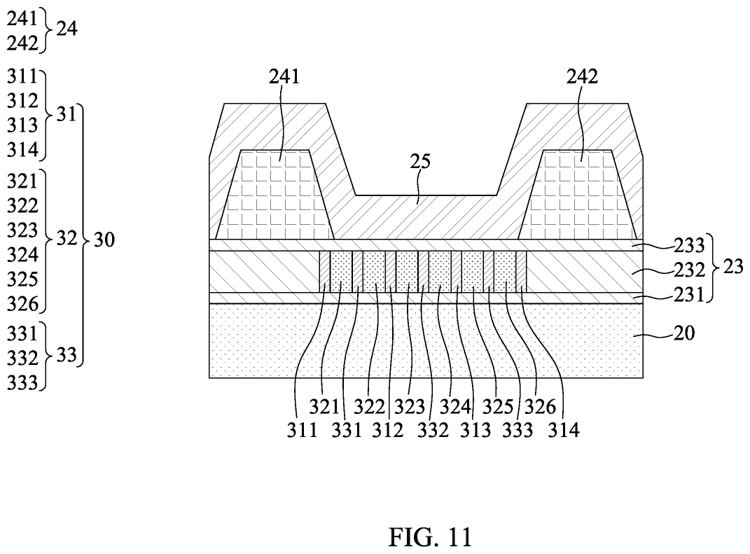

Referring to FIG. 11, a capacitor structure 30 having laterally arranged first electrodes 31, insulators 32 and second electrodes 33 is disposed within a first passivation structure 23 over an interconnect structure 20 in accordance with some embodiments of the present disclosure.

In some embodiments, the first electrode 31 includes multiple portions 311, 312, 313 and 314. In some embodiments, the portions 311, 312, 313 and 314 are electrically or physically connected. In some embodiments, the second electrode 33 includes multiple portions 331, 332 and 333. In some embodiments, the portions 331, 332 and 333 are electrically or physically connected. In some embodiments, insulator 32 includes multiple portions 321, 322, 323, 324, 325 and 326. In some embodiments, each of the portions 321, 322, 323, 324, 325 and 326 is disposed between adjacent portions of the first electrode 31 and the second electrode 33. In some embodiments, a thickness of the capacitor structure 30 is substantially equal to a thickness of a second passivation layer 232. In some embodiments, a top surface of the capacitor structure 30 is a substantially planar surface and aligned with a top surface of the second passivation layer 232. In some embodiments, a bottom surface of the capacitor structure 30 is a substantially planar surface and aligned with a bottom surface of the second passivation layer 232.

A configuration from a top view of the capacitor structure 30 can be designed according to different applications. In some embodiments, the capacitor structure 30 is an interdigital capacitor. In some embodiments, the capacitor structure 30 is a finger capacitor. In some embodiments, the capacitor structure 30 has an electrode having a configuration of a brush, a fishbone or the like.

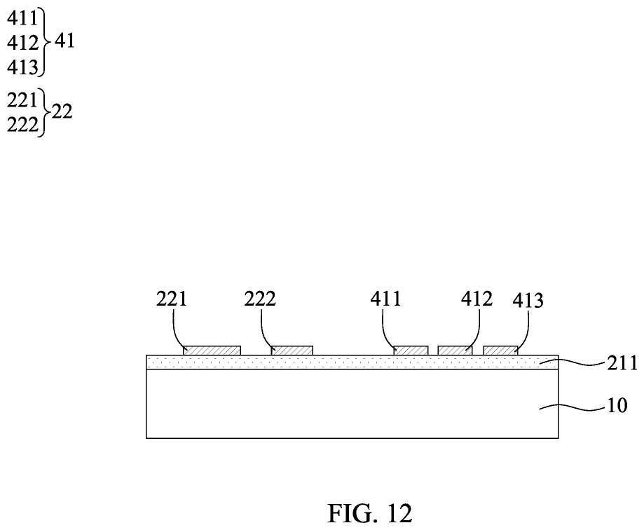

FIGS. 12 to 21 are schematic cross-sectional diagrams showing formation of a capacitor structure 40 in an interconnect structure 20 at different stages of a manufacturing method in accordance with some embodiments of the present disclosure.

Referring to FIG. 12, lower electrodes 41 (including lower electrodes 411, 412 and 413) are formed over an IMD layer 211 over a substrate 10. The IMD layer 211 can be any IMD layer of the interconnect structure 20 over the substrate 10. For a purpose of illustration and simplicity of the figures, layers (including metal line layers, via layers and IMD layers) below the IMD layer 211 are omitted from the figures. However, such omission is not intended to limit the present disclosure. In some embodiments, the lower electrodes 41 are disposed in a metal line layer including metal lines 221 and 222. In some embodiments, the lower electrodes 41 are formed concurrently with the metal lines 221 and 222 in the same metal line layer by, for example, a single patterning operation. In some embodiments, thicknesses of the lower electrodes 41 and the metal lines 221 and 222 are substantially equal to one another. The IMD layer 211 can include oxide, nitride, oxynitride, or a combination thereof. In some embodiments, the IMD layer 211 includes a low-k dielectric material. In some embodiments, a dielectric constant of the IMD layer 211 is substantially equal to or less than 3.9.

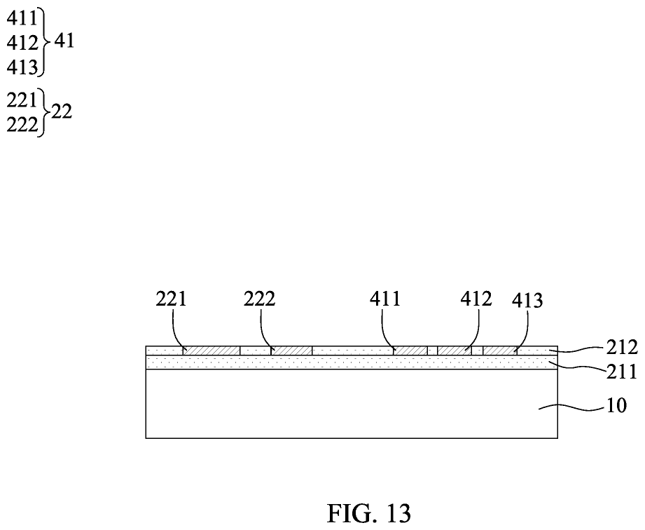

Referring to FIG. 13, an IMD layer 212 is formed over the IMD layer 211 and surrounding the metal lines 221 and 222 and the lower electrodes 41. In some embodiments, the IMD layer 212 laterally surrounds the metal lines 221 and 222 and the lower electrodes 41 without covering the metal lines 221 and 222 and the lower electrodes 41. In some embodiments, top surfaces of the metal lines 221 and 222 and the lower electrodes 41 are substantially aligned with a top surface of the IMD layer 212. All IMD layers (including the IMD layers 211 and 212) of the interconnect structure 20 to be formed include similar or same dielectric materials, and repeated description is omitted herein.

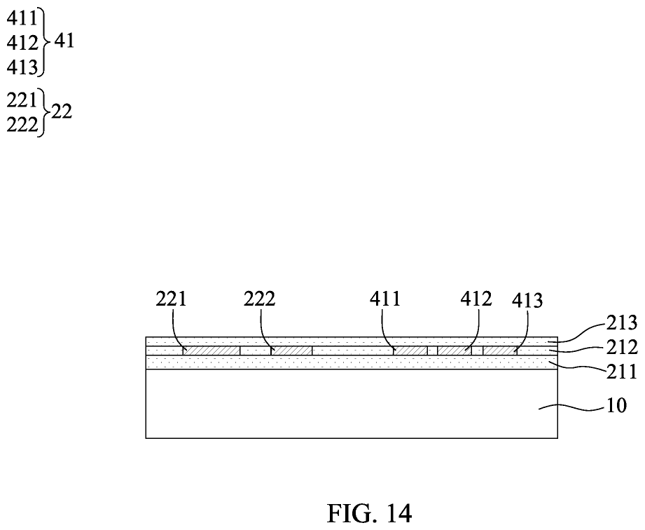

Referring to FIG. 14, an IMD layer 213 is formed over the lower electrodes 41 and the IMD layer 212. In some embodiments, the IMD layer 213 covers an entirety of the lower electrodes 41 and metal lines 22 (including the metal lines 221 and 222) in the same metal line layer. In some embodiments, the IMD layer 213 covers an entirety of the IMD layer 212. In some embodiments, a top surface of the IMD layer 213 is substantially planar.

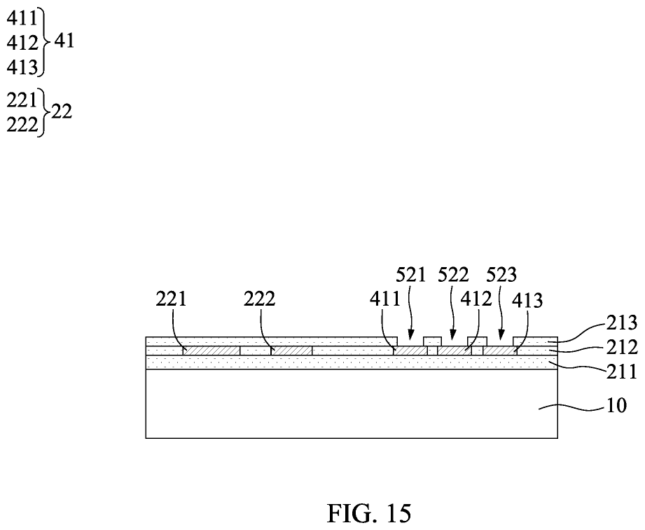

Referring to FIG. 15, openings 521, 522 and 523 of the IMD layer 213 are formed to expose portions of the lower electrodes 411, 412 and 413, respectively. In some embodiments, an etching operation is performed to form the openings 521, 522 and 523. In some embodiments, a patterned mask layer is formed over the IMD layer 213 prior to the etching operation. In some embodiments, the etching operation is performed on the IMD layer 213 using the patterned mask layer as a mask.

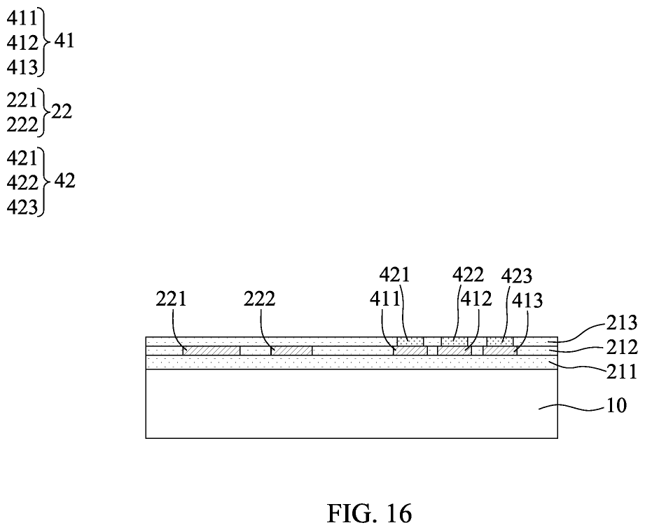

Referring to FIG. 16, insulators 42 (including insulators 421, 422 and 423) are formed in the openings 521, 522 and 523. In some embodiments, operations as depicted in FIG. 7 are applied to the intermediate structure of FIG. 15 to form the insulators 42 shown in FIG. 16. In some embodiments, each of the insulators 42 is laterally surrounded by the IMD layer 213. In some embodiments, the insulators 42 are in direct contact with the IMD layer 213. In some embodiments, a dielectric constant of the insulators 42 is in a range of 8 to 30. In some embodiments, the insulator 421 is disposed within an area of a vertical projection of the lower electrode 411. In some embodiments, the insulator 422 is disposed within an area of a vertical projection of the lower electrode 412. In some embodiments, the insulator 423 is disposed within an area of a vertical projection of the lower electrode 413. In some embodiments, top surfaces of the insulators 42 are substantially aligned with a top surface of the IMD layer 213.

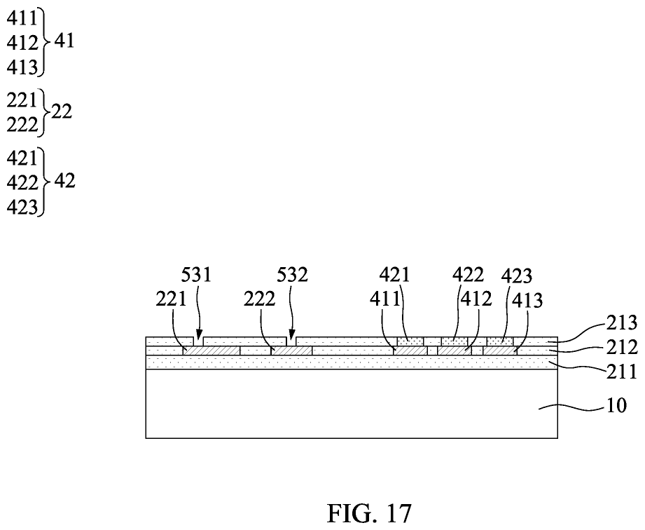

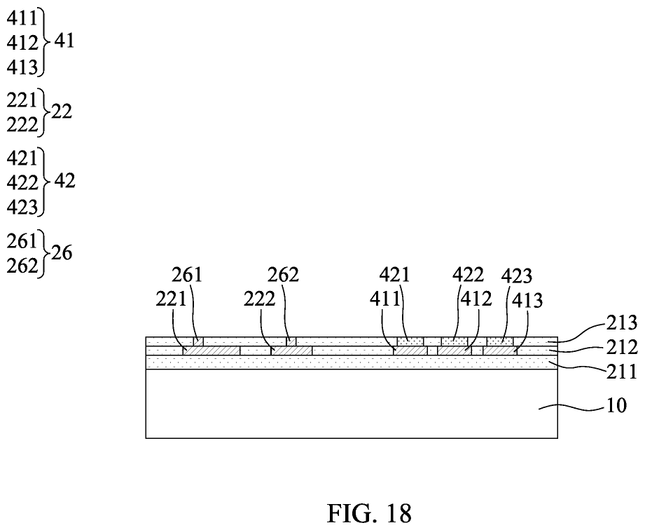

Referring to FIGS. 17 and 18, operations as depicted in FIGS. 15 and 16 are performed to form a plurality of metal vias 26 (including metal vias 261 and 262) filling openings 531 and 532 of the IMD layer 213. Formation of the metal vias 26 shown in FIGS. 17 and 18 can be performed prior to or after the formation of the insulators 42 shown in FIGS. 15 and 16 depending on different embodiments. In some embodiments, the openings 531 and 532 and the openings 521, 522 and 523 are defined by different photomasks. In some embodiments, the metal vias 26 are formed in one of multiple metal via layers of the interconnect structure 20. In some embodiments, the metal vias 26 are at a same layer (or a same elevation) as the insulators 42. In some embodiments, top surfaces of the metal vias 26 and the insulators 42 are substantially aligned with a top surface of the IMD layer 213.

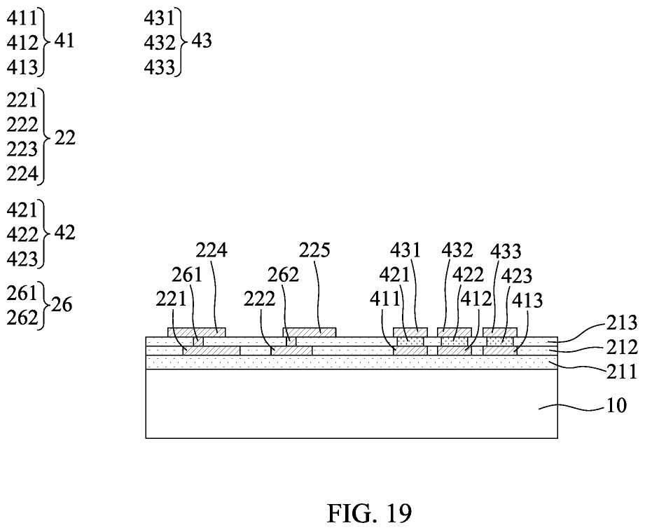

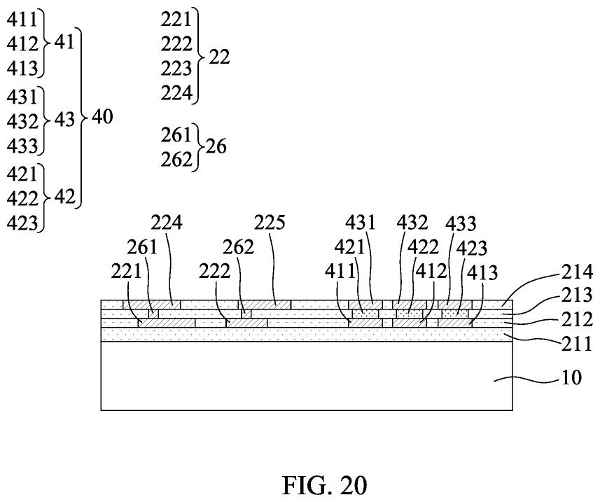

Referring to FIGS. 19 and 20, operations as depicted in FIGS. 12 and 13 are performed to form upper electrodes 43 (including upper electrodes 431, 432 and 433) concurrently with metal lines 224 and 225 and an IMD layer 214 surrounding the upper electrodes 43 and the metal lines 224 and 225. In some embodiments, the upper electrode 431 overlaps an entirety of the insulator 421. In some embodiments, the upper electrode 432 overlaps an entirety of the insulator 422. In some embodiments, the upper electrode 433 overlaps an entirety of the insulator 423. In some embodiments, the insulator 421, 422 or 423 is disposed within an area of a vertical projection of the upper electrode 431, 432 or 433, respectively.

In some embodiments, a capacitor structure 40 (including vertically stacked upper electrodes 43, insulators 42 and lower electrodes 41) vertically extends across at least two metal line layers. However, the present disclosure is not limited thereto. The capacitor structure 40 can vertically extend across one, two, three, or more metal line layers depending one different applications.

Referring to FIG. 21, a first passivation structure 23, a plurality of contact features 24 (only one is shown), and a second passivation structure 25 are sequentially formed over the interconnect structure 20. In some embodiments, the capacitor structure 40 is disposed in the top metal layers (including metal line layers Mn and Mn−1). In some embodiments, the upper electrodes 43 are disposed in a topmost metal line layer Mn. In some embodiments, the lower electrodes 41 are disposed in a metal line layer Mn−1, which is a first metal line layer below the topmost metal line layer Mn. For a purpose of comprehensive consideration of manufacturing cost and moisture detection, a capacitor structure 30 in the first passivation structure 23 is omitted in some embodiments of the present disclosure, since the capacitor structure 40 is close to the first passivation structure 23 and a crack in the first passivation structure 23 can still be easily detected by the capacitor structure 40 in the top metal layers of the interconnect structure 20. However, the present disclosure is not limited thereto.

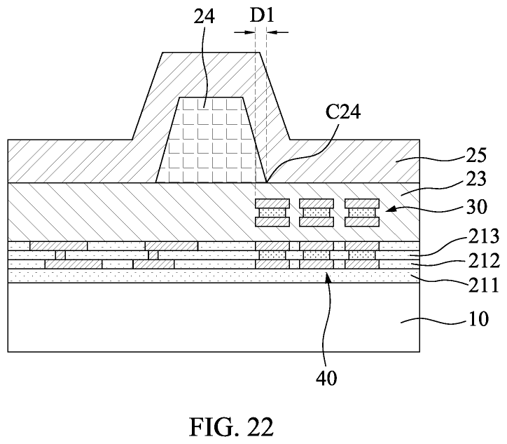

Referring to FIG. 22, a capacitor structure 30 is formed in a first passivation structure 23 over the intermediate structure of FIG. 20 in accordance with another embodiment of the present disclosure. In some embodiments, the capacitor structure 30 is at least partially within an area of a vertical projection of the capacitor structure 40 for a purpose of detection of a position and a depth of a crack. In some embodiments, the capacitor structure 30 and the capacitor structure 40 are vertically aligned.

As illustrated above, the capacitor structures 30 and 40 function as moisture detectors or crack detectors, and it is more efficient to place the capacitor structures 30 and 40 at locations where more stresses are incurred, such as an edge or a corner of a conductive feature. Therefore, the capacitor structure 30 is proximal to a lower corner (or a lower edge) of a contact feature 24. The capacitor structure 30 can be overlapped or not overlapped by the contact feature 24 as long as the capacitor structure 30 is proximal to a corner or an edge of the contact feature 24.

A shown in FIG. 22, in some embodiments, the capacitor structure 30 is overlapped by a peripheral region of the contact feature 24. In some embodiments, the lower corner C24 of the contact feature 24 overlaps the capacitor structure 30. In some embodiments, a width D1 of an overlapping area of the capacitor structure 30 and the contact feature 24 is in a range of 0.1 to 1 μm, wherein the width D1 is measured between an edge of the contact feature 24 and an edge of the capacitor structure 30. It should be noted that FIG. 22 shows only one contact feature 24 for a purpose of illustration. The capacitor structure 30 can be disposed between two adjacent contact features 24, and the capacitor structure 30 can be overlapped by at least one of the two adjacent contact features 24.

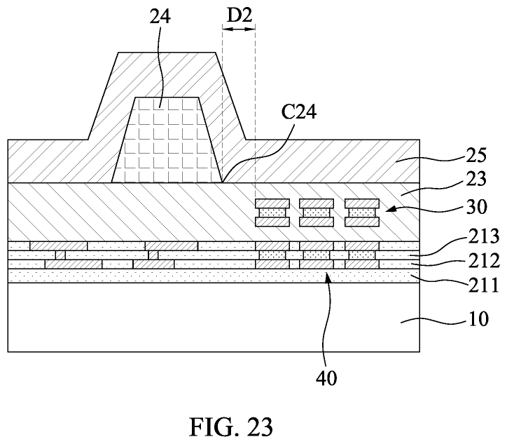

As shown in FIG. 23, in other embodiments, the capacitor structure 30 is not overlapped by the contact feature 24. In some embodiments, a distance D2 between an edge of the contact feature 24 and an edge of the capacitor structure 30 is in a range of 0.1 to 1 μm. It should be noted that FIG. 23 shows only one contact feature 24 for a purpose of illustration. The capacitor structure 30 can be disposed between two adjacent contact features 24, and the capacitor structure 30 can be overlapped by none, one or both of the two adjacent contact features 24.

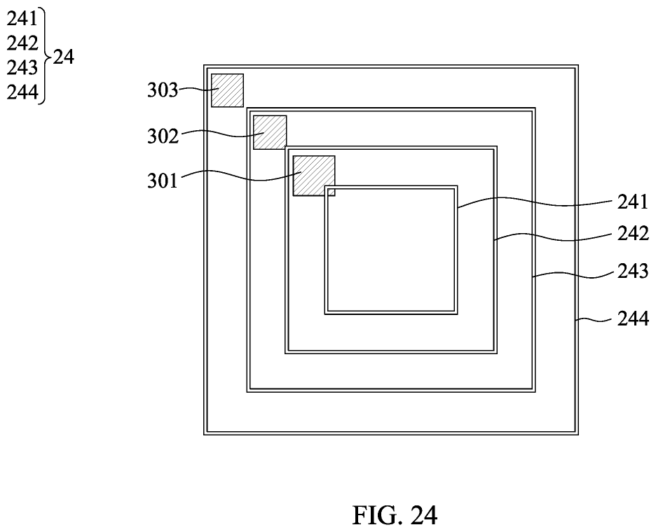

FIGS. 24 to 26 are top-view perspectives showing contact features 24 and capacitor structures 30 in accordance with different embodiments of the present disclosure. Reference numerals 301, 302, 303, 304 and 305 represent different capacitor structures 30, and reference numerals 241, 242, 243, 244, 245 and 246 represent different contact features 24. It should be noted that a number of the capacitor structures 30 and a number of the contact features 24 shown in the different figures are for a purpose of illustration, but are not intended to limit the present disclosure.

In some embodiments as shown in FIG. 24, each of the contact features 24 has a rectangular configuration. In some embodiments, each of the contact features 24 has a square configuration. In some embodiments, the contact feature 244 surrounds the contact feature 243, the contact feature 243 surrounds the contact feature 242, and the contact feature 242 surrounds the contact feature 241. In some embodiments, the capacitor structure 301 is disposed between corners of the rectangles of the contact features 241 and 242. In some embodiments, the capacitor structure 301 is overlapped by the corner of the rectangle of the contact feature 241. In some embodiments, the capacitor structure 302 is disposed between corners of the rectangles of the contact features 242 and 243. In some embodiments, the capacitor structure 303 is disposed between corners of the rectangles of the contact features 243 and 244. The capacitor structure 302 may or may not be overlapped by the contact feature 242 and/or the contact feature 243 according to different applications.

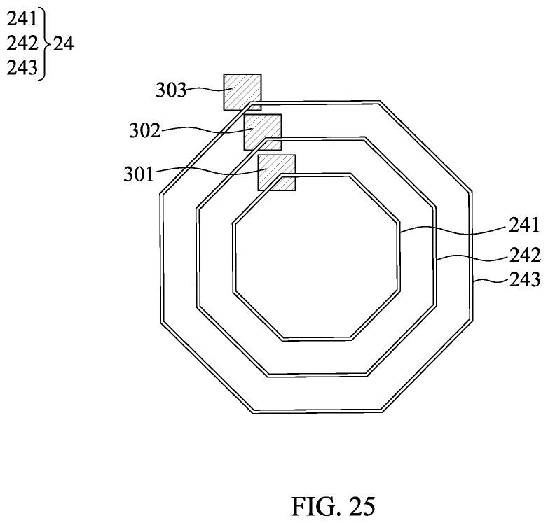

In some embodiments as shown in FIG. 25, each of the contact features 24 has a polygonal configuration. In some embodiments, each of the contact features 24 has an octagonal configuration. In some embodiments, the contact feature 243 surrounds the contact feature 242, and the contact feature 242 surrounds the contact feature 241. In some embodiments, the capacitor structure 301 is disposed between corners of the polygons of the contact features 241 and 242. In some embodiments, the capacitor structure 301 is overlapped by the corner of the polygon of the contact feature 241. In some embodiments, the capacitor structure 302 is disposed between corners of the polygons of the contact features 242 and 243. In some embodiments, the capacitor structure 302 is overlapped by the corner of the polygon of the contact feature 242. In some embodiments, the capacitor structure 303 is overlapped by the corner of the polygon of the contact feature 243.

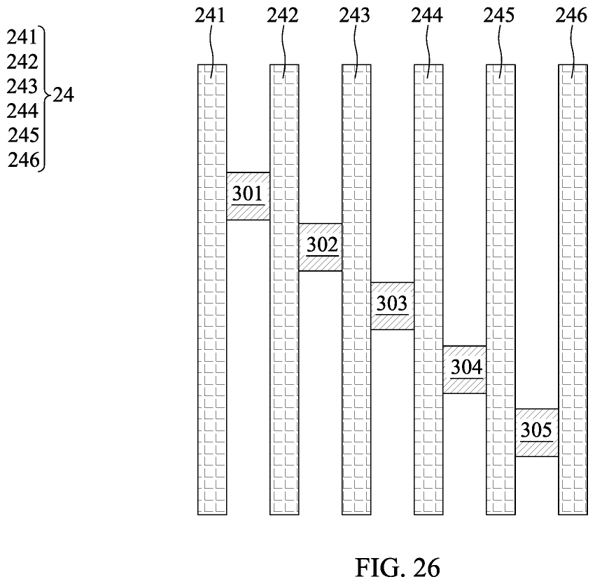

In some embodiments as shown in FIG. 26, each of the contact features 24 has a straight line configuration. In some embodiments, the capacitor structures 301, 302, 303, 304 and 305 are alternately arranged with the contact features 241, 242, 243, 244, 245 and 246. It should be noted that different configurations of the contact features 24 may result in different stresses on surrounding dielectric layers (e.g., the passivation structures 23 and 25). For example, a smaller angle between two sides of a contact feature 24 results in a greater stress on the surrounding dielectric layers. Therefore, in some embodiments, configurations of the contact features 24 shown in FIGS. 24, 25 and 26 can be combined or adjusted according to different applications to reduce total stresses on the passivation structures 23 and 25.

To conclude the processes of different embodiments as described above, a method 700 is provided.

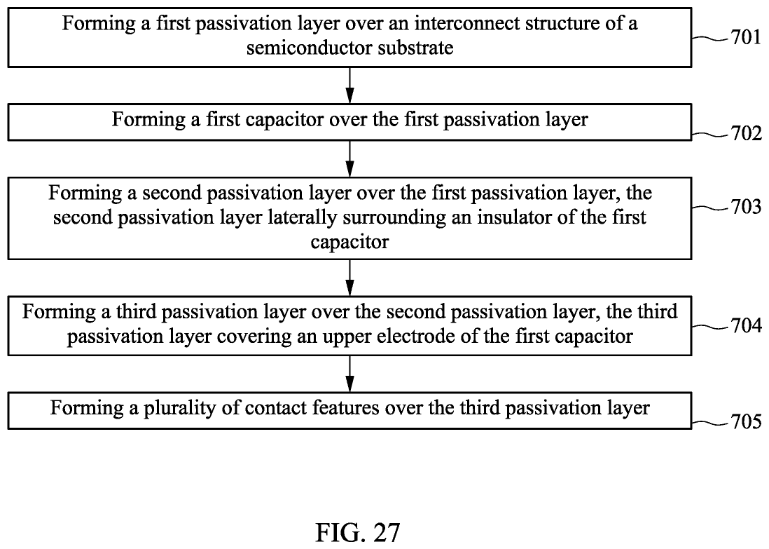

FIG. 27 is a flow diagram of the method 700 for manufacturing a semiconductor structure in accordance with some embodiments of the present disclosure. The method 700 includes a number of operations (701, 702, 703, 704 and 705), and the description and illustration are not deemed as a limitation to the sequence of the operations. In the operation 701, a first passivation layer is formed over an interconnect structure of a semiconductor substrate. In the operation 702, a first capacitor is formed over the first passivation layer. In the operation 703, a second passivation layer is formed over the first passivation layer, wherein the second passivation layer laterally surrounds an insulator of the first capacitor. In the operation 704, a third passivation layer is formed over the second passivation layer, wherein the third passivation layer covers an upper electrode of the first capacitor. In the operation 705, a plurality of contact features are formed over the third passivation layer.

It should be noted that the operations of the method 700 can be rearranged or otherwise modified within the scope of the various aspects. In some embodiments, additional processes are provided before, during, and after the method 700, and some other processes are only briefly described herein. Thus, other implementations are possible within the scope of the various aspects described herein.

In accordance with some embodiments of the disclosure, a semiconductor structure is provided. The semiconductor structure includes an interconnect structure, a passivation structure, a first capacitor, and a contact feature. The interconnect structure is disposed over a semiconductor substrate. The passivation structure is disposed over the interconnect structure. The first capacitor is disposed within the passivation structure. The contact feature is disposed over the passivation structure, wherein the first capacitor is proximal to a corner of the contact feature.

In accordance with some embodiments of the disclosure, a semiconductor structure is provided. The semiconductor structure includes an interconnect structure, a first passivation structure, a capacitor, a first contact feature and a second contact feature. The interconnect structure is disposed over a substrate. The first passivation structure is disposed over the interconnect structure. The capacitor is surrounded by the first passivation structure, wherein the capacitor includes an insulator having a dielectric constant substantially greater than a dielectric constant of the first passivation structure. The first contact feature is disposed over the first passivation structure. The second contact feature is adjacent to the first contact feature, wherein the capacitor is between the first contact feature and the second contact feature.

In accordance with some embodiments of the disclosure, a method for manufacturing a semiconductor structure is provided. The method may include several operations. A first passivation layer is formed over an interconnect structure of a semiconductor substrate. A first capacitor is formed over the first passivation layer. A second passivation layer is formed over the first passivation layer, wherein the second passivation layer laterally surrounds an insulator of the first capacitor. A third passivation layer is formed over the second passivation layer, wherein the third passivation layer covers an upper electrode of the first capacitor. A plurality of contact features are formed over the third passivation layer.

The foregoing outlines features of several embodiments so that those skilled in the art may better understand aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor structure, comprising:
an interconnect structure, disposed over a semiconductor substrate;
a passivation structure, disposed over the interconnect structure;
a first capacitor, disposed within the passivation structure; and
a contact feature, disposed over the passivation structure, wherein the first capacitor is proximal to a corner of the contact feature.

2. The semiconductor structure of claim 1, wherein the interconnect structure includes a plurality of metal line layers, and the semiconductor structure further comprises:
a second capacitor, disposed at least in a topmost metal line layer of the plurality of metal line layers.

3. The semiconductor structure of claim 2, wherein the second capacitor is overlapped by the first capacitor.

4. The semiconductor structure of claim 1, wherein the contact feature has a polygonal configuration from a top view.

5. The semiconductor structure of claim 4, wherein at least a portion of a corner of the polygonal configuration of the contact feature overlaps the first capacitor from the top view.

6. The semiconductor structure of claim 1, wherein the first capacitor includes an electrode and a high-k dielectric insulator, and the high-k dielectric insulator is disposed within an area of a vertical projection of the electrode.

7. The semiconductor structure of claim 6, wherein a dielectric constant of a material of the high-k dielectric insulator is in a range of 8 to 30, the high-k dielectric insulator is laterally surrounded by a dielectric material of the passivation structure, and the dielectric material of the passivation structure has a dielectric constant lower than that of the material of the high-k dielectric insulator.

8. A semiconductor structure, comprising:
an interconnect structure, disposed over a substrate;
a first passivation structure, disposed over the interconnect structure;
a capacitor, surrounded by the first passivation structure, wherein the capacitor includes an insulator having a dielectric constant substantially greater than a dielectric constant of the first passivation structure;
a first contact feature, disposed over the first passivation structure; and
a second contact feature, adjacent to the first contact feature, wherein the capacitor is between the first contact feature and the second contact feature.

9. The semiconductor structure of claim 8, wherein the capacitor is overlapped by at least one of the first contact feature and the second contact feature.

10. The semiconductor structure of claim 8, wherein a horizontal distance between an edge of the capacitor and a corner of the first contact feature is in a range of 0.1 to 1 microns.

11. The semiconductor structure of claim 8, wherein a vertical distance between a bottom surface of the first contact feature and a top surface of the capacitor is in a range of 0.2 to 0.6 microns.

12. The semiconductor structure of claim 8, further comprising:
a second passivation structure, disposed over the first contact feature, the second contact feature and the first passivation structure, wherein the capacitor is covered by the second passivation structure.

13. The semiconductor structure of claim 8, wherein a distance between the capacitor and a top surface of the interconnect structure is in a range of 0.2 to 0.6 microns.

14. The semiconductor structure of claim 8, wherein a thickness of the capacitor is in a range of 0.2 to 0.4 microns.

15. The semiconductor structure of claim 8, wherein the first contact feature has a polygonal configuration, and the capacitor is at least overlapped by a corner of the polygonal configuration from a top-view perspective.

16. The semiconductor structure of claim 8, wherein the insulator of the capacitor is in direct contact with the first passivation structure.

17. A method of manufacturing a semiconductor structure, comprising:
forming a first passivation layer over an interconnect structure of a semiconductor substrate;
forming a first capacitor over the first passivation layer;
forming a second passivation layer over the first passivation layer, the second passivation layer laterally surrounding an insulator of the first capacitor;
forming a third passivation layer over the second passivation layer, the third passivation layer covering an upper electrode of the first capacitor; and
forming a plurality of contact features over the third passivation layer.

18. The method of claim 17, further comprising:
forming a fourth passivation layer over the plurality of contact features and the third passivation layer.

19. The method of claim 17, wherein the forming of the first capacitor comprises:
forming a lower electrode of the first capacitor over the first passivation layer;
forming an opening of the second passivation layer, thereby exposing a portion of the lower electrode;
filling the opening with a high-k dielectric material, thereby forming the insulator surrounded by the second passivation layer; and
forming the upper electrode of the first capacitor over the insulator prior to the formation of the third passivation layer.

20. The method of claim 17, further comprising:
forming a second capacitor in the interconnect structure, wherein the second capacitor is proximal to a bottom surface of the first passivation layer.
